(19) United States
(12) Patent Application Publication
(10) Pub. No.: US 2021/0310739 A1
(43) Pub. Date: Oct. 7, 2021

(54) CLEANING METHOD AND HEAT TREATMENT APPARATUS

(71) Applicant: Tokyo Electron Limited, Tokyo (JP)

(72) Inventors: Tomoya HASEGAWA, Tokyo (JP); Tsubasa WATANABE, Yamanashi (JP)

(21) Appl. No.: 17/216,694

(22) Filed: Mar. 30, 2021

(30) Foreign Application Priority Data
Apr. 7, 2020 (JP) 2020-068794

(51) Int. Cl. F27D 25/00; B08B 9/027; F27D 11/02; F27B 17/00

(52) U.S. Cl. CPC F27D 25/008; F27B 17/0025; F27D 11/02; B08B 9/027

(57) ABSTRACT

A cleaning method introduces a cleaning gas containing hydrogen fluoride into a reaction tube included in a heat treatment apparatus and having a furnace portion at one end in a state where an inside of the reaction tube with the furnace port being closed by a lid is maintained at a temperature at which water exists as a liquid film and the furnace port is locally heated, thereby removing a deposit from the reaction tube.

### CROSS-REFERENCE TO RELATED APPLICATIONS

This application is based on and claims priority from Japanese Patent Application No. 2020-068794 filed on Apr. 7, 2020 with the Japan Patent Office, the disclosure of which is incorporated herein in its entirety by reference.

### TECHNICAL FIELD

The present disclosure relates to a cleaning method and a heat treatment apparatus.

### BACKGROUND

A technology is known in which an inside of a reaction tube of a heat treatment apparatus is set to room temperature and a cleaning gas containing hydrogen fluoride and nitrogen is introduced into the reaction tube to remove the reaction products adhering to the inside of the apparatus (see, e.g., Japanese Patent Laid-Open Publication No. 2011-077543).

### SUMMARY

A cleaning method according to an aspect of the present disclosure is a cleaning method for removing deposits in a reaction tube including a furnace port at one end. The cleaning method includes a step of removing the deposits by introducing a cleaning gas containing hydrogen fluoride into the reaction tube in a state where an inside of the reaction tube with the furnace port being closed by a lid is maintained at a temperature at which water exists as a liquid film, and also the furnace port is locally heated.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a heat treatment apparatus of an embodiment.

FIG. 2 is a time chart illustrating an example of a cleaning method of an embodiment.

FIGS. 3A to 3C are views illustrating positional relationships between a reaction tube and a lid in the cleaning method of the embodiment.

FIG. 4 is a view illustrating calculation results of etching amounts of quartz and SiO₂.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, non-limiting exemplary embodiments of the present disclosure will be described with reference to the accompanying drawings. In all of the accompanying drawings, the same or corresponding members or parts are denoted by the same or corresponding reference numerals, and redundant explanations are omitted.

[Heat Treatment Apparatus]

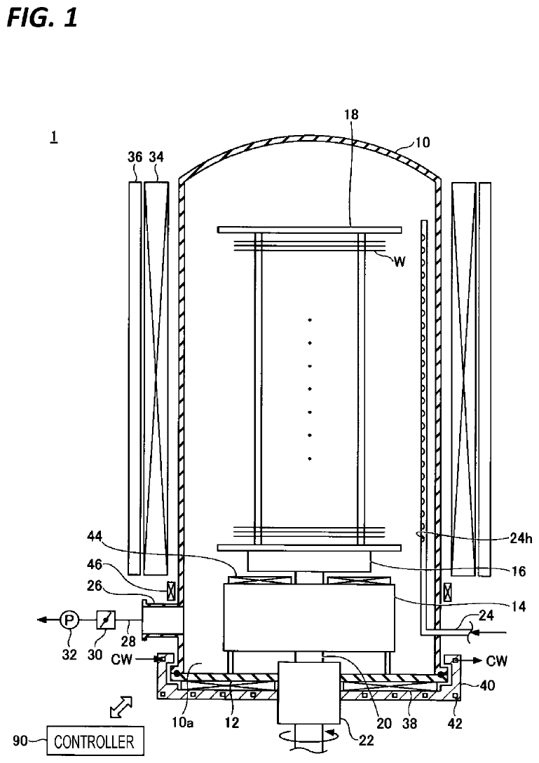

Descriptions will be made on an example of a heat treatment apparatus of an embodiment with reference to FIG. 1. FIG. 1 is a view illustrating an example of the heat treatment apparatus of the embodiment.

A heat processing apparatus 1 includes a reaction tube 10. The reaction tube 10 has a substantially cylindrical shape having a ceiling with a longitudinal direction directed in the vertical direction, and has a furnace port 10a at one end (lower end). The reaction tube 10 is formed of a material that is excellent in heat resistance and corrosion resistance, for example, quartz.

The furnace port 10a of the reaction tube 10 is closed by a lid 12. The lid 12 is formed of a material that is excellent in heat resistance and corrosion resistance, for example, quartz. The lid 12 is configured to be movable up and down by a boat elevator (not illustrated). When the lid 12 is raised, the furnace port 10a of the reaction tube 10 is closed, and when the lid 12 is lowered, the furnace port 10a of the reaction tube 10 is opened.

A heat insulating cylinder 14 is provided on the upper portion of the lid 12. The heat insulating cylinder 14 includes a plurality of substantially disc-shaped quartz fins (not illustrated) having a predetermined interval in the vertical direction and disposed substantially horizontally. The heat insulating cylinder 14 has a function of heat insulating such that a temperature of the lower end area of the reaction tube 10 is not excessively decreased due to heat radiation from the furnace port 10a of the reaction tube 10.

A rotary table 16 is provided above the heat insulating cylinder 14. The rotary table 16 functions as a stage on which a wafer boat 18 is rotatably placed. A rotary shaft 20 is provided below the rotary table 16, and the rotary shaft 20 penetrates the center of the heat insulating cylinder 14, and is connected to a rotating mechanism (not illustrated) configured to rotate the rotary table 16 via a magnetic fluid seal 22.

The wafer boat 18 substantially horizontally holds semiconductor wafers (hereinafter, referred to as “wafers W”) with predetermined intervals in the vertical direction. The wafer boat 18 is made of, for example, quartz. The wafer boat 18 is disposed on the rotary table 16. As a result, when the rotary table 16 is rotated, the wafer boat 18 is rotated, and the wafer W held by the wafer boat 18 is rotated by the rotation.

A gas introducing pipe 24 is inserted through the side surface of the reaction tube 10 near the lower end to introduce a processing gas into the reaction tube 10. The gas introducing pipe 24 is provided to be bent in an L shape so as to penetrate the reaction tube 10, extend into the inside of the reaction tube 10, and stand up vertically upward along the inner wall surface of the reaction tube 10. The gas introducing pipe 24 includes a plurality of gas holes 24h at predetermined intervals along the longitudinal direction. The gas holes 24h eject the processing gas in the horizontal direction. Therefore, the processing gas is supplied from the periphery of the wafer W substantially in parallel with the main surface of the wafer W. The processing gas may include, for example, a film forming gas for forming a thin film on the wafer W, and a cleaning gas for removing deposits (reaction products) adhering to the inside of the heat treatment apparatus 1. The cleaning gas is composed of a gas containing hydrogen fluoride (HF), and for example, is composed of a mixed gas of hydrogen fluoride gas and nitrogen gas serving as a diluting gas. Although FIG. 1 illustrates a case where one gas introducing pipe 24 is inserted into the reaction tube 10, a plurality of gas introducing pipes 24 may be inserted.

Further, an exhaust port 26 is formed on the side surface of the reaction tube 10 near the lower end and the gas in the reaction tube 10 is exhausted through the exhaust port 26. An exhaust pipe 28 is connected to the exhaust port 26. A pressure adjusting valve 30 and a vacuum pump 32 are sequentially interposed in the exhaust pipe 28, and the inside of the reaction tube 10 may be exhausted by the vacuum pump 32 while adjusting the pressure in the reaction tube 10 by the pressure adjusting valve 30.

Around the reaction tube 10, a chamber heater 34 and a first cooling jacket 36 are provided in this order from the reaction tube 10 side to surround the reaction tube 10. The chamber heater 34, which is an example of a first heater, is, for example, a cylindrical heater including a resistance heating element, and heats the entire reaction tube 10 to heat the wafer W in the reaction tube 10. The first cooling jacket 36 includes a coolant flow path therein through which a coolant such as cooling water may flow, and cools the inside of the reaction tube 10 by heat radiation by allowing the coolant to flow through the coolant flow path. The coolant may include, for example, cooling water (CW).

A cap heater 38 is provided below the lid 12. The cap heater 38, which is an example of a second heater, is, for example, a planar heater including a resistance heating element, and locally heats the furnace port 10a of the reaction tube 10. Therefore, the temperature of the lower portion of the reaction tube 10 is suppressed from being lower than the temperature of the upper portion and the intermediate portion of the reaction tube 10, and temperature uniformity of the reaction tube 10 in the vertical direction is improved.

A second cooling jacket 40 is provided on the side and below the lid 12 to cover the lid 12 and the cap heater 38. The second cooling jacket 40 includes a coolant flow path 42 therein through which a coolant may flow, and cools the lid 12 by heat conduction by allowing the coolant to flow through the coolant flow path 42. The coolant may include, for example, cooling water.

A heat insulating cylinder heater 44 is provided on the upper portion of the heat insulating cylinder 14. The heat insulating cylinder heater 44, which is an example of a second heater, is, for example, a planar heater including a resistance heating element, and locally heats the furnace port 10a of the reaction tube 10. Therefore, the temperature of the lower portion of the reaction tube 10 is suppressed from being lower than the temperature of the upper portion and the intermediate portion of the reaction tube 10, and temperature uniformity of the reaction tube 10 in the vertical direction is improved.

A lower heater 46 is provided at substantially the same height as the heat insulating cylinder 14 around the reaction tube 10. The lower heater 46, which is an example of a second heater, is, for example, a cylindrical heater including a resistance heating element, and locally heats the furnace port 10a of the reaction tube 10. Therefore, the temperature of the lower portion of the reaction tube 10 is suppressed from being lower than the temperature of the upper portion and the intermediate portion of the reaction tube 10, and temperature uniformity of the reaction tube 10 in the vertical direction is improved.

Further, the heat treatment apparatus 1 includes a controller 90. The controller 90 controls each part of the heat treatment apparatus 1. The controller 90 may be, for example, a computer. Further, a computer program for executing an operation of each component of the heat treatment apparatus 1 is stored in a storage medium. The storage medium may be, for example, a flexible disk, a compact disk, a hard disk, a flash memory, and a DVD.

In the above, an example of the heat treatment apparatus has been described. However, the form of the heat treatment apparatus is not limited to the above mentioned apparatus and may include various configurations.

[Cleaning Method]

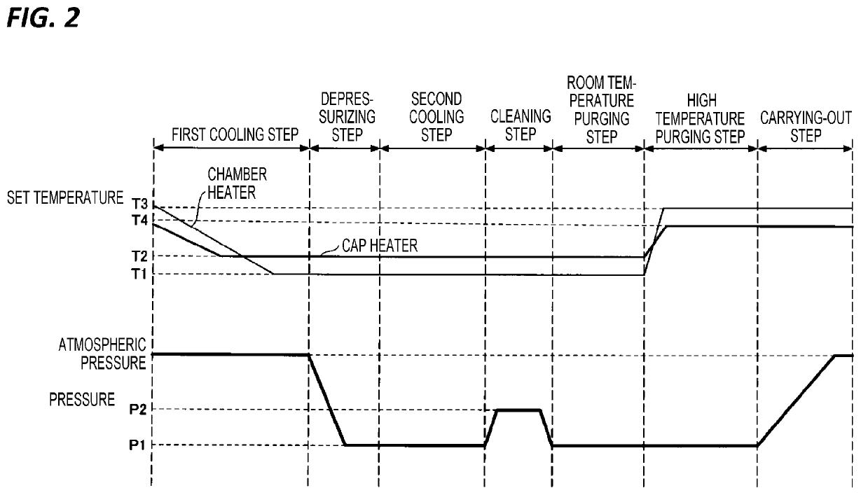

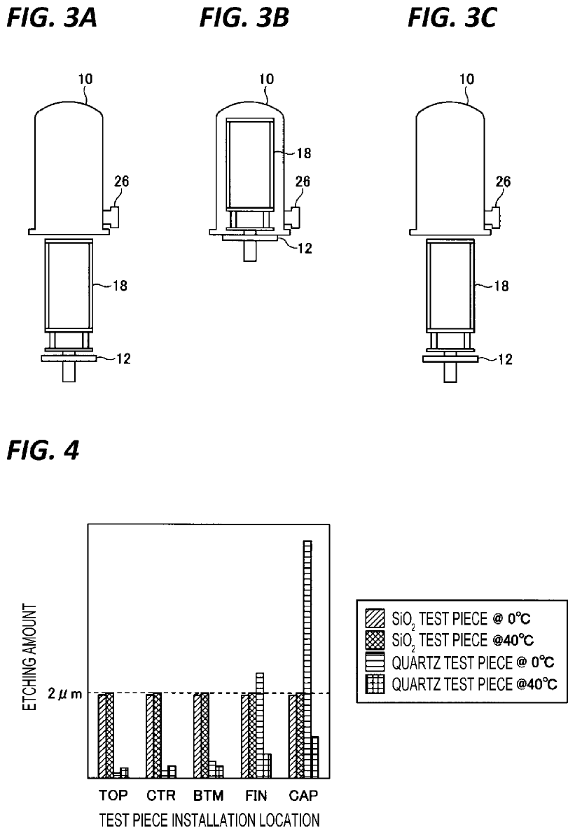

Descriptions will be made on an example of a cleaning method of an embodiment with reference to FIGS. 2 and 3A to 3C. FIG. 2 is a time chart illustrating the example of the cleaning method of the embodiment. FIGS. 3A to 3C are views illustrating positional relationships between the reaction tube 10 and the lid 12 in the cleaning method of the embodiment.

In the following, descriptions will be made on an exemplary case where silicon oxide adhering to the inside of the heat treatment apparatus 1 is removed by performing a process of forming silicon oxide (SiO₂) on the wafer W in the reaction tube 10 of the heat treatment apparatus 1.

As illustrated in FIG. 2, the cleaning method of the embodiment includes a first cooling step, a depressurizing step, a second cooling step, a cleaning step, a room temperature purging step, a high temperature purging step, and a carrying-out step.

As illustrated in FIG. 3A, the first cooling step is implemented in a state where the wafer boat 18 is carried out from the inside of the reaction tube 10, and the inside of the reaction tube 10 is at atmospheric pressure. In the first cooling step, the controller 90 cools the reaction tube 10 by heat radiation by the first cooling jacket 36, and cools the lid 12 by heat conduction by the second cooling jacket 40. Further, the controller 90 sets a set temperature of the chamber heater 34 to a first temperature T1. The first temperature T1 is a temperature at which water (H₂O) may exist as a liquid film inside the reaction tube 10, for example, on the surface of the reaction tube 10. The first temperature T1 is, for example, 0° C. to 100° C., and may be room temperature (25° C.). As described above, since the inside of the reaction tube 10 is set to the temperature at which water may exist as a liquid film on the surface of the reaction tube 10, in the cleaning step (to be described later), water produced by the reaction between hydrogen fluoride and silicon oxide exists as a liquid film on the surface of the reaction tube 10. The water reacts with intermediate products produced from the reaction products in the cleaning step, and as a result, the reaction products may be removed.

By the way, in the first cooling step, the lower side of the reaction tube 10 that is cooled by heat conduction is more likely to be cooled than the upper portion and the intermediate portion of the reaction tube 10 cooled by heat radiation. Therefore, in the first cooling step, the controller 90 sets a set temperature of the cap heater 38 to a second temperature T2 higher than the first temperature T1, which is the set temperature of the chamber heater. Therefore, the temperature of the lower portion of the reaction tube 10 is suppressed from being lower than the temperature of the upper portion and the middle portion of the reaction tube 10, and temperature uniformity of the reaction tube 10 in the vertical direction is improved. As a result, in the cleaning step (to be described later), a liquid film is suppressed from being excessively generated on the surfaces of the lid 12 and the heat insulating cylinder 14 provided in the lower portion of the reaction tube 10 with respect to the surface of the wafer boat 18 provided in the upper portion and the intermediate portion of the reaction tube 10. As a result, it is possible to suppress the lid 12 and the heat insulating cylinder 14 from being etched when the silicon oxide adhering to the inside of the reaction tube 10 in the cleaning step.

In the depressurizing step, as illustrated in FIG. 3B, the controller 90 raises the lid 12 by the boat elevator to carry the wafer boat 18 into the reaction tube 10. Further, the controller 90 exhausts the inside of the reaction tube 10 by the vacuum pump 32, and reduces the pressure inside the reaction tube 10 to a first pressure P1. The first pressure P1 is, for example, a pressure completely sucked by the vacuum pump 32. Further, the controller 90 maintains the set temperature of the chamber heater 34 at the first temperature T1, and maintains the set temperature of the cap heater 38 at the second temperature T2.

As illustrated in FIG. 3B, the second cooling step is implemented in a state where the wafer boat 18 is accommodated in the reaction tube 10. In the second cooling step, in a state where the pressure inside the reaction tube 10 is reduced to the first pressure P1, the controller 90 cools the reaction tube 10 by heat radiation by the first cooling jacket 36, and cools the lid 12 by heat conduction by the second cooling jacket 40. Further, the controller 90 maintains the set temperature of the chamber heater 34 at the first temperature T1, and maintains the set temperature of the cap heater 38 at the second temperature T2.

As illustrated in FIG. 3B, the cleaning step is implemented in the state where the wafer boat 18 is accommodated in the reaction tube 10. In the cleaning step, the controller 90 maintains the set temperature of the chamber heater 34 at the first temperature T1, and maintains the set temperature of the cap heater 38 at the second temperature T2. Further, the controller 90 introduces the cleaning gas composed of a gas containing hydrogen fluoride from the gas introducing pipe 24 into the reaction tube 10, and adjusts the pressure inside the reaction tube 10 to a second pressure P2. The second pressure P2 is, for example, a pressure between the first pressure P1 and the atmospheric pressure. When the cleaning gas is introduced into the reaction tube 10, hydrogen fluoride reacts with the silicon oxide adhering to the inside of the heat treatment apparatus 1, for example, the inner wall of the reaction tube 10, the lid 12, the heat insulating cylinder 14, and the wafer boat 18 to produce intermediate products and water. At this time, since the inside of the reaction tube 10 is set to the temperature at which water may exist as a liquid film on the surface of the reaction tube 10, water exists as a liquid film on the surface of the reaction tube 10. The water further reacts with the produced intermediate products to produce, for example, water-soluble intermediate products, and the produced water-soluble intermediate products may be removed from the reaction tube 10. As a result, the silicon oxide adhering to the inside of the heat treatment apparatus 1 is removed.

Further, in the cleaning step, the controller 90 maintains the set temperature of the cap heater 38 at the second temperature T2 higher than the first temperature T1, which is the set temperature of the chamber heater. Therefore, the temperature of the lower portion of the reaction tube 10 is suppressed from being lower than the temperature of the upper portion and the intermediate portion of the reaction tube 10, and temperature uniformity of the reaction tube 10 in the vertical direction is improved. As a result, in the cleaning step (to be described later), a liquid film is suppressed from being excessively generated on the surfaces of the lid 12 and the heat insulating cylinder 14 provided in the lower portion of the reaction tube 10 with respect to the surface of the wafer boat 18 provided in the upper portion and the intermediate portion of the reaction tube 10. As a result, it is possible to suppress the lid 12 and the heat insulating cylinder 14 from being etched when the silicon oxide adhering to the inside of the reaction tube 10.

As illustrated in FIG. 3B, the room temperature purging step is implemented in the state where the wafer boat 18 is accommodated in the reaction tube 10. In the room temperature purging step, the controller 90 maintains the set temperature of the chamber heater 34 at the first temperature T1, and maintains the set temperature of the cap heater 38 at the second temperature T2. Further, in the room temperature purging step, the controller 90 discharge the gas in the reaction tube 10, and introduces a predetermined amount of nitrogen from the gas introducing pipe 24 to discharge the gas in the reaction tube 10 to the exhaust pipe 28. At this time, in order to efficiently discharge the gas in the reaction tube 10, the discharge of the gas in the reaction tube 10 and the supply of nitrogen may be repeated a plurality of times.

As illustrated in FIG. 3B, the high temperature purging step is implemented in the state where the wafer boat 18 is accommodated in the reaction tube 10. In the high temperature purging step, the controller 90 sets the set temperature of the chamber heater 34 to a third temperature T3 higher than the first temperature T1, and sets the set temperature of the cap heater to a fourth temperature T4 higher than the second temperature T2. The third temperature T3 is, for example, 350° C., and the fourth temperature T4 is, for example, 300° C. Further, the controller 90 discharge the gas in the reaction tube 10, and introduces a predetermined amount of nitrogen from the gas introducing pipe 24 to discharge the gas in the reaction tube 10 to the exhaust pipe 28. At this time, in order to efficiently discharge the gas in the reaction tube 10, the discharge of the gas in the reaction tube 10 and the supply of nitrogen may be repeated a plurality of times. Since the high temperature purging step is implemented at the temperature higher than that of the room temperature purging step, the water in the reaction tube 10 may be reliably removed. Even if the inside of the reaction tube 10 is heated to a high temperature, the cleaning gas is not introduced into the reaction tube 10. Thus, it is possible to suppress deterioration of parts of the heat treatment apparatus 1 such as the reaction tube 10.

In the carrying-out step, the controller 90 supplies a predetermined nitrogen from the gas introducing pipe 24 into the reaction tube 10 to return the pressure in the reaction tube 10 to the atmospheric pressure. Subsequently, as illustrated in FIG. 3C, the controller 90 lowers the lid 12 by the boat elevator to carry the wafer boat 18 out from the inside of the reaction tube 10.

As described above, the silicon oxide adhering to the inside of the heat treatment apparatus 1 may be removed.

### Example

Descriptions will be made on an example carried out to confirm the effect exhibited by the cleaning method of the embodiment with reference to FIG. 4.

In the example, first, a test piece made of quartz glass (hereinafter, referred to as a “quartz test piece”) and a test piece obtained by forming 2 μm of silicon oxide (SiO₂) on the surface of a quartz test piece (hereinafter, referred to as a “SiO₂ test piece”) are prepared.

Subsequently, the wafer boat 18 is carried out from the inside of the reaction tube 10 that is heated to a temperature at which a film forming processing is performed.

Subsequently, the reaction tube 10 and the lid 12 are cooled in a state where the set temperature of the chamber heater 34 is set to 0° C., and the set temperature of the cap heater 38 is set to 0° C. or 40° C. under the atmospheric pressure environment.

Subsequently, the prepared quartz test piece and SiO₂ test piece are installed on the upper portion, the intermediate portion, and the lower portion of the wafer boat 18, on the lower portion of the heat insulating cylinder 14, and on the upper surface of the lid 12, respectively, and the wafer boat 18 is carried into the reaction tube 10.

Subsequently, the pressure inside the reaction tube 10 is reduced, and the temperature of the inside of the reaction tube 10 is stabilized to room temperature. Subsequently, the cleaning gas containing hydrogen fluoride (2 slm/min) and nitrogen is supplied into the reaction tube 10 for 45 minutes.

Subsequently, the reaction tube 10 is purged in a state where the set temperature of the chamber heater 34 is set to 0° C., and the set temperature of the cap heater 38 is set to 0° C. or 40° C., and thus, the remained gas in the reaction tube 10 is removed.

Subsequently, the reaction tube 10 is purged in a state where the inside of the reaction tube 10 is heated by raising the set temperature of the chamber heater 34 to 350° C., and raising the set temperature of the cap heater 38 to 300° C., and thus, the remained gas in the reaction tube 10 is removed.

Subsequently, after returning the pressure inside the reaction tube 10 to an atmospheric pressure, the wafer boat 18 is carried out from the inside of the reaction tube 10.

Subsequently, the thicknesses of the quartz test pieces and the SiO₂ test pieces installed on the upper portion, the intermediate portion, and the lower portion of the wafer boat 18, on the lower portion of the heat insulating cylinder 14, and on the upper surface of the lid 12 are measured by a spectroscopic ellipsometer. Further, the etching amounts of quartz and SiO₂ are calculated based on the measured thicknesses, and the thicknesses of the quartz test pieces and the SiO₂ test pieces before being carried into the reaction tube 10.

FIG. 4 is a view illustrating calculation results of etching amounts of quartz and SiO₂. In FIG. 4, the horizontal axis represents the installation of the quartz test piece and the SiO₂ test piece, and the vertical axis represents the etching amount. In FIG. 4, “TOP”, “CTR”, and “BTM” represent the results of the quartz test piece and the SiO₂ test piece installed on the top portion, the intermediate portion, and the lower portion of the wafer boat 18, respectively. Further, “FIN” and “CAP” represent the quartz test piece and the SiO₂ test piece installed on the lower portion of the heat insulating cylinder 14 and the upper surface of the lid 12, respectively.

As illustrated in FIG. 4, when the set temperature of the cap heater 38 is 40° C., it may be seen that, at all the installation locations, the etching amount of SiO₂ is larger than the etching amount of quartz, and is approximately 2 μm. From the results, it may be said that, when the set temperature of the cap heater 38 is 40° C., at all the installation locations, SiO₂ may be completely removed while quartz is hardly etched.

Meanwhile, when the set temperature of the cap heater 38 is 0° C., it may be seen that, at all the installation locations, the etching amount of SiO₂ is 2 μm, but the etching amount of quartz is larger than the etching amount of SiO₂ on the lower portion of the heat insulating cylinder 14 and the upper surface of the lid 12. From the results, it may be said that, when the set temperature of the cap heater 38 is 0° C., quartz is etched in the lower portion of the reaction tube 10 when SiO₂ is completely removed at all the installation locations.

As described above, according to the embodiment, deposits adhering to the inside of the heat treatment apparatus 1 may be removed by using a gas containing hydrogen fluoride as a cleaning gas. Further, since the temperature of the inside of the reaction tube 10 is room temperature, it is possible to suppress deterioration of parts of the heat treatment apparatus 1 such as the reaction tube 10 in the cleaning step. Further, in the cleaning step, the cleaning gas containing hydrogen fluoride is introduced into the reaction tube 10 in a state where the inside of the reaction tube 10 is maintained at a temperature at which water may exist as a liquid film and the furnace port 10a is locally heated, and thus, the deposits in the reaction tube 10 may be removed. Therefore, it is possible to suppress over-etching of members such as the lid 12 and the heat insulating cylinder 14 provided in the vicinity of the furnace port 10a of the reaction tube 10. As a result, the life of the member may extend, and further, particles generated by etching the member may be reduced.

In the above-described embodiment, descriptions have been made on the case where the furnace port 10a of the reaction tube 10 is locally heated by the cap heater 38 in the cleaning step, but the present disclosure is not limited thereto. For example, the furnace port 10a of the reaction tube 10 may be heated by the heat insulating cylinder heater 44 or the lower heater 46 instead of the cap heater 38. Further, the furnace port 10a of the reaction tube 10 may be heated by a combination of at least two of the cap heater 38, the heat insulating cylinder heater 44, and the lower heater 46.

Further, in the above-described embodiment, descriptions have been made on the case where the exhaust port 26 is formed on the side surface of the reaction tube 10 near the lower end, but the position of the exhaust port 26 is not limited thereto. For example, the exhaust port 26 may be formed on the ceiling of the reaction tube 10.

Further, in the above-described embodiment, descriptions have been made on the case where the reaction tube 10 is a single tube, but the present disclosure is not limited thereto. For example, the reaction tube 10 may be a double tube.

According to the present disclosure, it is possible to suppress the over-etching of the member provided in the vicinity of the furnace port of the reaction tube.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method for cleaning a heat treatment apparatus, the method comprising:
introducing a cleaning gas containing hydrogen fluoride into a reaction tube included in the heat treatment and having a furnace port at one end in a state where an inside of the reaction tube with the furnace port being closed by a lid is maintained at a temperature at which water exists as a liquid film and the furnace port is locally heated, thereby removing a deposit from the reaction tube.

2. The method according to claim 1, wherein the temperature at which water exists as a liquid film is room temperature.

3. The method according to claim 2, wherein, in the introducing the cleaning gas, the lid is heated to a same temperature as the temperature at which water exists as a liquid film.

4. The method according to claim 3, wherein the heat treatment apparatus further includes a first heater configured to heat an entire reaction tube, and a second heater configured to locally heat the furnace port, and
in the introducing the cleaning gas, a set temperature of the second heater is set to be higher than a set temperature of the first heater.

5. The method according to claim 4, wherein the second heater includes a cap heater provided below the lid.

6. The method according to claim 5, wherein a heat insulating cylinder is provided above the lid, and
the second heater includes a heat insulating cylinder heater provided on an upper portion of the heat insulating cylinder.

7. The method according to claim 6, wherein the second heater includes a lower heater provided at a substantially same height as the heat insulating cylinder around the reaction tube.

8. The method according to claim 7, wherein, the introducing the cleaning gas includes cooling the reaction tube and the lid.

9. The method according to claim 8, further comprising:
after the introducing the cleaning gas, heating the inside of the reaction tube at a temperature at which water is removed and exhausting a gas in the reaction tube, thereby removing the water in the reaction tube.

10. The method according to claim 9, wherein the lid is made of quartz.

11. The method according to claim 1, wherein, in the introducing the cleaning gas, the lid is heated to a same temperature as the temperature at which water exists as a liquid film.

12. The method according to claim 1, wherein the heat treatment apparatus further includes a first heater configured to heat an entire reaction tube, and a second heater configured to locally heat the furnace port, and
in the introducing the cleaning gas, a set temperature of the second heater is set higher than a set temperature of the first heater.

13. The method according to claim 12, wherein the second heater includes a cap heater provided below the lid.

14. The method according to claim 12, wherein the heat insulating cylinder is provided above the lid, and
the second heater includes a heat insulating cylinder heater provided on an upper portion of the heat insulating cylinder.

15. The method according to claim 12, wherein the second heater includes a lower heater provided at a substantially same height as the heat insulating cylinder around the reaction tube.

16. The method according to claim 1, wherein, the including the cleaning gas includes cooling the reaction tube and the lid.

17. The method according to claim 1, further comprising:
after the including the cleaning gas, heating the inside of the reaction tube at a temperature at which water is removed and exhausting a gas in the reaction tube, thereby removing the water in the reaction tube.

18. The method according to claim 1, wherein the lid is made of quartz.

19. A heat treatment apparatus comprising:
a reaction tube having a furnace port at one end;
a gas introducing pipe configured to introduce a cleaning gas containing hydrogen fluoride into the reaction tube;
a first heater provided around the reaction tube;
a lid configured to close the furnace port of the reaction tube;
a second heater configured to heat the lid; and
a controller configured to control an overall operation of the heat treatment apparatus,
wherein the controller is configured to introduce a cleaning gas from the gas introducing pipe into the reaction tube with the furnace port being closed by the lid, in a state where an inside of the reaction tube is maintained at a temperature at which water exists as a liquid film by controlling the first heater and the lid is heated by controlling the second heater.
